(19) United States
(12) Patent Application Publication
(10) Pub. No.: US 2007/0152281 A1
(43) Pub. Date: Jul. 5, 2007

(54) NARROW WIDTH METAL OXIDE SEMICONDUCTOR TRANSISTOR HAVING A SUPPLEMENTAL GATE CONDUCTOR PATTERN

(76) Inventor: Jung Ho Ahn, Chungbuk (KR)

Correspondence Address: SHERR & NOURSE, PLLC, 620 HERNDON PARKWAY, SUITE 200, HERNDON, VA, 20170, US

(21) Appl. No.: 11/616,255

(22) Filed: Dec. 26, 2006

(30) Foreign Application Priority Data
Dec. 29, 2005 (KR) 10-2005-0134091

(51) Int. Cl. H01L 29/76

(52) U.S. Cl. 257/401

(57) ABSTRACT

A MOS transistor may include at least one of: a channel having a width W0 and a length L0; an active area with a channel between a source area and a drain area; a gate insulating layer formed over a channel; and/or a gate conductor formed over a gate insulating layer and intersecting the active area. In embodiments, a gate conductor may include at least one of: a connection pattern formed with a gate contact hole which electrically connects the gate conductor to the outside; an additional pattern connected to a connection pattern and positioned in parallel with both source and drain areas while being spaced apart from the active area at a certain distance; and a channel pattern connected to an additional pattern in the shape of a T and defining the length of a channel.

The present application claims priority under 35 U.S.C. 119 and 35 U.S.C. 365 to Korean Patent Application No. 10-2005-0134091 (filed on Dec. 29, 2005), which is hereby incorporated by reference in its entirety.

### BACKGROUND

Transistors with a relatively small scale may have a narrow width. Reverse narrow width effects and/or short channel effects may cause complications in a transistor. A portion of a gate electrode may overlap an isolation area. A narrow width effect may be influenced by parasitic charges due to a bird's beak of an isolation layer and/or field stop impurities. A narrow width effect may cause more charges to be supplied when a gate forms a channel of a transistor. A threshold voltage of a transistor may be relatively high when a channel width is relatively narrow, which may be advantageous.

Although a threshold voltage of a transistor may be relatively high due to a channel width being relatively narrow, the threshold voltage of the transistor may be decreased because of a manufacturing process. For example, if a field oxide layer is formed and ion implantation is performed on the field oxide layer, impurities may be distributed in a field area of a transistor at a lower density than in a channel area of the transistor. For example, if an isolation area is formed through STI (Shallow Trench Isolation), threshold voltage may decrease and may cause currents to increase.

If an isolation area of a transistor with a narrow channel width is formed with LOCOS (Local Oxidation of Silicon), a threshold voltage may increase.

If channel lengths and widths of PMOS and NMOS transistors are adjusted to enhance their performance, the performance of one transistor may be enhanced but the performance of the other transistor may be deteriorated. It may be desirable to simultaneously enhance the performance of both PMOS and NMOS transistors when enhancing the performance of transistors, such as current driving performance.

### SUMMARY

Embodiments relate to a semiconductor transistor which may have enhanced performance as both PMOS and NMOS transistors. In embodiments, driving current performance may be enhanced, while reducing a narrow width effect. In embodiments, an additional pattern may be added to a gate conductor. In embodiments, a MOS transistor may have enhanced current driving performance and may have a narrow channel width.

In embodiments, a MOS transistor may be made of a metal oxide semiconductor. A MOS transistor may include at least one of: a channel having a width W0 and a length L0; an active area with a channel between a source area and a drain area; a gate insulating layer formed over a channel; and/or a gate conductor formed over a gate insulating layer and intersecting the active area. In embodiments, a gate conductor may include at least one of: a connection pattern formed with a gate contact hole which electrically connects the gate conductor to the outside; an additional pattern connected to a connection pattern and positioned in parallel with both source and drain areas while being spaced apart from the active area at a certain distance; and a channel pattern connected to an additional pattern in the shape of a T and defining the length of a channel. A distance by which an additional pattern is spaced apart from an active area is almost identical to the length of a channel.

### BRIEF DESCRIPTION OF THE DRAWINGS

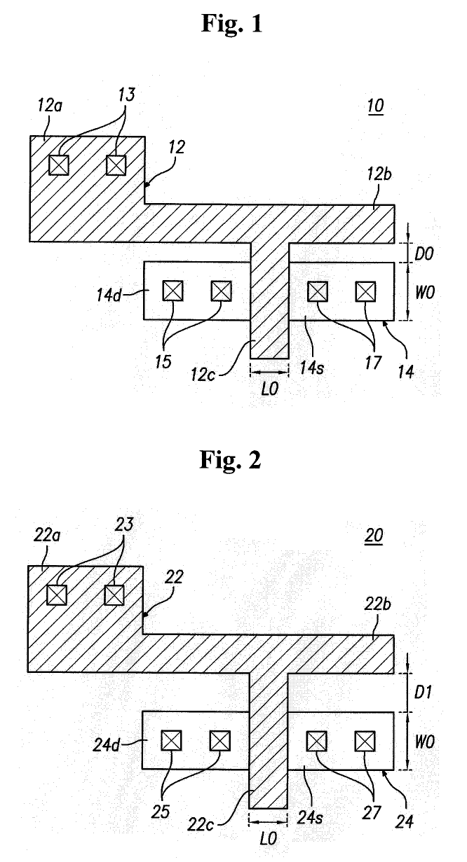

Example FIGS. 1 through 4 illustrates transistors, in accordance with embodiments.

### DETAILED DESCRIPTION

Example FIG. 1 is a plan layout view illustrating structural characteristics of a transistor, according to embodiments. Gate conductor 12 may be made of poly-silicon. Gate conductor 12 may intersect active area 14. Active area 14 may be implanted or diffused with impurities (e.g. N-type impurities such as P, As and N, or P-type impurities such as B, Ga and In) in a semiconductor (e.g. silicon) substrate. Active area 14 may be divided into a source area 14s and a drain area 14d, with gate conductor 12 overlapping active area 14.

A gate insulating layer may be formed beneath a surface of gate conductor 12 and may overlap with active area 14. Gate conductor 12 may be electrically isolated from active area 14. Gate conductor 12 may be electrically connected to the outside (e.g. a gate electrode) through gate contact holes 13. Source area 14s and drain area 14d may be electrically connected to the outside through source contact hole 17 and drain contact hole 15. Gate conductor 12 may include a connection pattern 12a having gate contact holes 13. Channel pattern 12c may determine the length of a channel and may intersect active area 14. Supplemental pattern 12b may connect connection pattern 12a and channel pattern 12c.

If a bias voltage (e.g. a positive (+) voltage in an NMOS transistor or a negative (−) voltage in a PMOS transistor) of at least a threshold voltage is applied to gate conductor 12, an electric field may be generated from a gate conductor. A channel may be formed below a gate insulating layer due to the influence of an electric field from gate conductor 12. If a channel is formed by a gate voltage, current may flow between source area 14s and drain area 14d. Current may not flow through a channel if a bias voltage is not present, which may be an operating principle of a transistor. A transistor that includes a semiconductor substrate, a gate insulating layer, and a gate conductor may be referred to as a MOS transistor.

MOS transistor 10 of FIG. 1 may be a narrow width transistor. Width W0 may be relatively small (e.g. approximately 0.3 μM). Channel length L0 may be 0.13 μm. In embodiments, MOS transistor 10 may include supplemental pattern 12b as part of gate conductor 12. Supplemental pattern 12b may be parallel to active area 14, in accordance with embodiments. In embodiments, supplemental pattern 12b may be spaced apart from active area 14 (e.g. at a distance D0 of approximately 0.07 μm).

MOS transistor 10 may have dimensions and structure which may be implemented in either a NMOS transistor or a PMOS transistor, in accordance with embodiments. In embodiments, for transistor 10 to have dimensions and structure to be implemented as either a NMOS transistor or a PMOS transistor, driving current of both the NMOS transistor and PMOS transistor may be approximately 100. In embodiments, a structure of a transistor may be optimized to a driving current by designing the structure and dimension of the transistor.

Driving current may be optimally enhanced in the structure and dimension of a transistor illustrated in FIG. 2, in accordance with embodiments. In a transistor illustrated in FIG. 2, performance enhancements may be implemented for both PMOS and NMOS transistors. Transistor 20 may include supplemental pattern 22b as part of gate conductor 22. Supplemental patter 22b may be parallel to both source area 24s and drain area 24d of active area 24. Supplemental pattern 22b may be connected to channel pattern 22c in the shape of a T.

Supplemental pattern 22b may be formed at the same time as forming gate conductor 22, in accordance with embodiments. In embodiments, only the pattern of a mask may need to be modified without the need for additional photo mask to form supplemental pattern 22b of gate conductor 22. In embodiments, formation of supplemental pattern 22b may not require significant modification of a semiconductor manufacturing process as additional processing steps may not be necessary.

According to embodiments, supplemental pattern 22b may be spaced apart from active area 24 by distance D1. In embodiments, distance D1 may be approximately 0.12 μM. In embodiments, distance D1 may be substantially the same as length L0 of channel pattern 22c. In embodiments, when transistor 20 is a NMOS transistor, the driving current of transistor 20 may be approximately 102.78% of the driving current of transistor 10 of FIG. 1. In embodiments, when transistor 20 is a PMOS transistor, the driving current of transistor 20 may be approximately 105.56% of the driving current of transistor 10 of FIG. 1.

In embodiments, when transistor 20 is a PMOS transistor, driving current may be 105.56% of transistor 10. In embodiments, current driving performance of transistor 20 may be at least about 103% of transistor 10 (e.g. as either a PMOS transistor or NMOS transistor). Transistor 20 may have enhanced performance as either a PMOS or NMOS transistor.

As illustrated in FIG. 2, transistor 20 may be a MOS transistor in which active area 24 has source area 24s and drain area 24d that intersect gate conductor 22. Gate conductor 22 may be connected electrically to the outside through gate contact holes 23. Source area 24s and drain area 24d may be electrically connected to the outside through source contact holes 27 and drain contact holes 25.

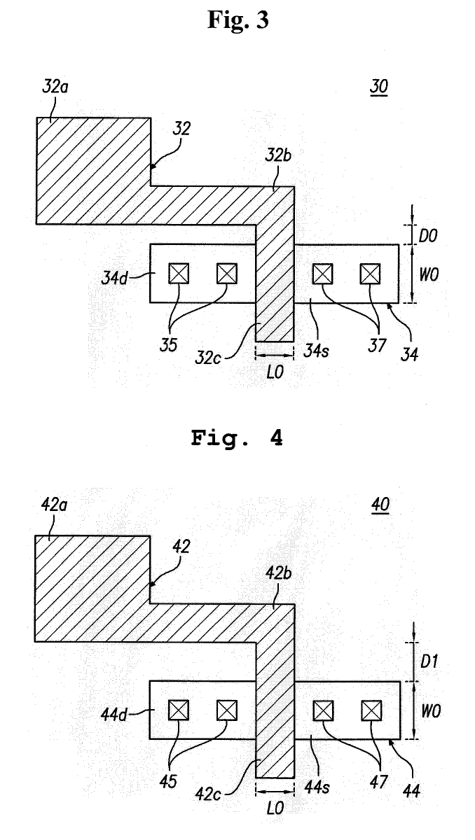

As illustrated in FIG. 3, transistor 30 may be a MOS transistor in which active area 34 has source area 34s and drain area 34d that intersect gate conductor 32. Gate conductor 32 may be electrically connected to the outside through gate contact holes. Source area 34s and drain area 34d may be electrically connected to the outside source contact holes 37 and drain contact holes 35. Gate conductor 32 may include connection pattern 32a, supplemental pattern 32b, and/or a channel pattern 32c, in accordance with embodiments.

In transistor 30, gate conductor 32 may include supplemental pattern 32b which may be parallel with drain area 34d, in accordance with embodiments. In embodiments, supplemental pattern 32b of transistor 30 may be connected to channel pattern 32c in the shape of a L, in accordance with embodiments. In embodiments, the distance between supplemental pattern 32b and drain area 34d may be distance D0. In embodiments, distance D0 may be approximately 0.07 μM. In embodiments, when transistor 30 is a NMOS transistor, the driving current of transistor 30 may be approximately 101.16% of the driving current of transistor 10 of FIG. 1. In embodiments, when transistor 30 is a PMOS transistor, the driving current of transistor 20 may be approximately 100.44% of the driving current of transistor 10 of FIG. 1.

As illustrated in FIG. 4, transistor 40 may be a MOS transistor in which active area 44 has source area 44s and drain area 44d that intersect gate conductor 42. Gate conductor 42 may be electrically connected to the outside through gate contact holes. Source area 44s and drain area 44d may be electrically connected to the outside source contact holes 47 and drain contact holes 45. Gate conductor 42 may include connection pattern 42a, supplemental pattern 42b, and/or a channel pattern 42c, in accordance with embodiments.

In transistor 40, gate conductor 42 may include supplemental pattern 42b which may be parallel with drain area 44d, in accordance with embodiments. In embodiments, supplemental pattern 42b of transistor 40 may be connected to channel pattern 42c in the shape of a L, in accordance with embodiments. In embodiments, the distance between supplemental pattern 42b and drain area 44d may be distance D1. In embodiments, distance D1 may be approximately 0.12 μm. In embodiments, when transistor 40 is a NMOS transistor, the driving current of transistor 40 may be approximately 101.62% of the driving current of transistor 10 of FIG. 1. In embodiments, when transistor 40 is a PMOS transistor, the driving current of transistor 40 may be approximately 102.78% of the driving current of transistor 10 of FIG. 1.

An comparison of channel widths, channel lengths, supplemental pattern structures, supplemental pattern separation distances, NMOS driving currents, and PMOS driving currents are compared for transistors 10, 20, 30, and 40 in Table 1. Supplemental pattern distances are the distance between supplemental patters 12b, 22b, 32b and 42b and the active areas 14, 24, 34, and 44 respectively.

TABLE 1

| | | | | Separation | | |
|---|---|---|---|---|---|---|
| | | | Structure of | of | NMOS | PMOS |
| | Channel | Channel | Supplemental | Supplemental | Driving | Driving |
| | Width | length | pattern | Pattern | Current | Current |
| Transistor 10 | 0.3 μm | 0.13 μm | T Shape | 0.07 μm | 100 | 100 |
| Transistor 20 | 0.3 μm | 0.13 μm | T Shape | 0.12 μm | 102.78% | 105.56% |
| Transistor 30 | 0.3 μm | 0.13 μm | L Shape | 0.07 μm | 101.16% | 100.44% |
| Transistor 40 | 0.3 μm | 0.13 μm | L Shape | 0.12 μm | 101.62% | 102.78% |

As illustrated in Table 1, the structure of transistor 10 and transistor 20 are the same, by having a T shape, in accordance with embodiments. By transistor 20 having a distance between the supplemental pattern 22 approximately equal to the channel length L0 both NMOS and PMOS transistors may be enhanced by at least approximately 103%. In embodiments, problems with driving control drops both PMOS and NMOS transistors may be minimized, which may be due to a narrow width effect with a relatively small channel width. In embodiments, driving current performance of a transistor may be improved without the need for additional manufacturing processes, which may minimize costs.

It will be apparent to those skilled in the art that various modifications and variations can be made to embodiments. Thus, it is intended that embodiments cover modifications and variations thereof within the scope of the appended claims.

What is claimed is:

1. An semiconductor device comprising a transistor, wherein the transistor comprises:
an active area; and
a gate conductor, wherein the gate conductor comprises a supplemental pattern parallel to the active area and a channel pattern that overlaps the active area.

2. The semiconductor device of claim 1, wherein the supplemental pattern is extends along the length of the active area.

3. The semiconductor device of claim 2, wherein the gate conductor has a L shape.

4. The semiconductor device of claim 1, wherein the supplemental pattern only extends along a portion of the length of the active area.

5. The semiconductor device of claim 4, wherein the gate conductor has a L shape.

6. The semiconductor device of claim 1, wherein the distance between the supplemental pattern and the active area is approximately the same as the width of the channel pattern.

7. The semiconductor device of claim 6, wherein the distance between the supplemental pattern and the active area is approximately 0.12 μm.

8. The semiconductor device of claim 1, wherein the distance between the supplemental pattern and the active area is less than the width of the channel pattern.

9. The semiconductor device of claim 8, wherein the distance between the supplemental pattern and the active area is approximately 0.07 μm.

10. The semiconductor device of claim 1, wherein the transistor is a narrow width transistor.

11. An method of forming a semiconductor device comprising a transistor, comprising:
forming an active area; and
forming a gate conductor, wherein the gate conductor comprises a supplemental pattern parallel to the active area and a channel pattern that overlaps the active area.

12. The method of claim 11, wherein the supplemental pattern is extends along the length of the active area.

13. The method of claim 12, wherein the gate conductor has a L shape.

14. The method of claim 11, wherein the supplemental pattern only extends along a portion of the length of the active area.

15. The method of claim 14, wherein the gate conductor has a L shape.

16. The method of claim 11, wherein the distance between the supplemental pattern and the active area is approximately the same as the width of the channel pattern.

17. The method of claim 16, wherein the distance between the supplemental pattern and the active area is approximately 0.12 μm.

18. The method of claim 11, wherein the distance between the supplemental pattern and the active area is less than the width of the channel pattern.

19. The method of claim 18, wherein the distance between the supplemental pattern and the active area is approximately 0.07 μm.

20. The method of claim 11, wherein the transistor is a narrow width transistor.
